(19) United States
(12) Patent Application Publication
(10) Pub. No.: US 2011/0076600 A1
(43) Pub. Date: Mar. 31, 2011

(54) Method For Manufacturing Parallax Barrier And Method For Manufacturing Photomask

(75) Inventor: Eiji NAKAYA, Nagano-ken (JP)

(73) Assignee: SEIKO EPSON CORPORATION, Tokyo (JP)

(21) Appl. No.: 12/883,849

(22) Filed: Sep. 16, 2010

(30) Foreign Application Priority Data
Sep. 29, 2009 (JP) 2009-224200

(51) Int. Cl. G03F 1/00; B05D 5/06

(52) U.S. Cl. 430/5; 427/164

(57) ABSTRACT

A method for manufacturing a parallax barrier including light blocking portions that block light and openings that transmit light, includes: a light-blocking layer formation step of forming a light-blocking layer on a light-transmissive substrate; a pattern formation step of forming the openings, which are formed of a plurality of rectangular ones, thereto; and a cutting step of cutting the light-transmissive substrate along a first cutting direction inclined to the first formation direction by a predetermined angle and a second cutting direction inclined to the second formation direction by the angle, in the pattern formation step, the plurality of openings disposed along the first formation direction formed in such a way that the openings are disposed stepwise shifted in the second formation direction and follow the first cutting direction.

### CROSS-REFERENCES TO RELATED APPLICATIONS

The entire disclosure of Japanese Patent Application No. 2009-224200, filed on Sep. 29, 2009, is expressly incorporated by reference herein.

### BACKGROUND

1. Technical Field

The present invention relates to a method for manufacturing a parallax barrier and a method for manufacturing a photomask.

2. Related Art

To allow a viewer to view a stereoscopic image, there has been a known parallax barrier used in combination with a display unit, such as a liquid crystal panel having a plurality of pixels. The parallax barrier separates a right-eye image and a left-eye image displayed on the display unit so that the right-eye and left-eye images are incident on the right and left eyes of the viewer, respectively.

The parallax barrier described above is configured in such a way that it is disposed to face the display unit and light blocking portions that block light and openings that transmit light are formed in a pattern on a light-transmissive substrate. In this configuration, the light blocking portions and the openings are alternately disposed at least in one direction in correspondence with the arrangement of the pixels of the display unit.

The pitch between the openings in the parallax barrier is preferably an ideal value defined based on the pitch between the pixels (distances between the pixels) of the display unit and the interpupillary distance (the distance between the eyes) of the viewer.

When the light blocking portions and the openings are formed in a pattern on the light-transmissive substrate, however, current pattern forming methods are only capable of controlling the precision in the pitch up to approximately 1 μm and are not capable of achieving an ideal pitch between the openings.

To address the problem, the openings have been formed in such a way that multiple types of pitch achievable by using a current pattern forming method are mixed so that the average of the multiple types of pitch provides an ideal value. This technique is proposed, for example, in JP-A-8-36145.

When multiple types of pitch are used to form the openings, however, the range within which the viewer can visually recognize pixels through any of the openings differs from the range obtained through the other openings.

That is, since a light-blocking pattern called a black matrix is typically formed over a plurality of pixels that form the display unit in order to separate the pixels, the black matrix is disadvantageously viewed by the viewer through part of the openings.

Further, when the openings are formed at the multiple types of pitch, openings through which a large portion of the black matrix is viewed greatly differ from openings through which a small portion of the black matrix is viewed in terms of brightness. In this case, the viewer disadvantageously views streaky interference fringes (moiré pattern).

As described above, the technique of the related art has a problem of degradation of the quality of a stereoscopic image due to a moiré pattern formed in the stereoscopic image.

It is conceivable to form the openings in such a way that the area thereof is small enough for the viewer not to be able to visually recognize the black matrix. In this case, however, the area through which light passes becomes smaller and hence the brightness of the stereoscopic image decreases. As a result, the stereoscopic image cannot be displayed in a satisfactory manner.

### SUMMARY

An advantage of some aspects of the invention is to provide a method for manufacturing a parallax barrier capable of displaying a stereoscopic image in a satisfactory manner.

According to a first aspect of the invention, there is provided a method for manufacturing a parallax barrier including light blocking portions that block light and openings that transmit light, the light blocking portions and the openings separating a right-eye image and a left-eye image displayed on a display unit having a plurality of pixels arranged in a matrix. The method includes a light-blocking layer formation step of forming a light-blocking layer that blocks light on a light-transmissive substrate, a pattern formation step of forming the openings, which are formed of a plurality of rectangular ones, by removing part of the light-blocking layer in such a way that the light blocking portions and the openings are alternately arranged along a first formation direction and a second formation direction perpendicular thereto, and a cutting step of cutting the light-transmissive substrate along a first cutting direction inclined to the first formation direction by a predetermined angle and a second cutting direction inclined to the second formation direction by the angle. In the pattern formation step, the plurality of openings disposed along the first formation direction are not only formed at an even pitch smaller than an ideal opening pitch for the parallax barrier in a row direction of the display unit, the ideal opening pitch defined based on a pixel pitch in the row direction, but also formed in such a way that the openings are disposed stepwise shifted in the second formation direction and follow the first cutting direction.

In the first aspect of the invention, when part of the light-blocking layer is removed to form the plurality of substantially rectangular openings in the pattern formation step, a plurality of openings disposed along the first formation direction are formed at an even pitch (hereinafter referred to as an opening pitch) achievable by a current pattern forming method and smaller than an ideal opening pitch. The parallax barrier is then manufactured in the cutting step by cutting the substrate along the first cutting direction inclined to the first formation direction by a predetermined angle (hereinafter referred to as a cutting angle) and the second cutting direction inclined to the second formation direction by the cutting angle.

When the thus manufactured parallax barrier is combined with the display unit in such a way that the row direction of the pixels of the display unit is aligned with the first cutting direction, the pitch along the first cutting direction (row direction) between the openings can be virtually closer to the ideal opening pitch even when the opening pitch, which is smaller than the ideal opening pitch, is provided in the pattern formation step.

More specifically, the pitch along the first cutting direction between the openings is given by B/cos θ, where B represents the opening pitch and θ represents the cutting angle. Therefore, for example, when the cutting angle θ is set at a value close to arccos(B/B′), where B′ represents the ideal opening pitch, the pitch along the first cutting direction between the openings can be substantially equal to the ideal opening pitch.

Further, in the pattern formation step, the plurality of openings disposed along the first formation direction are formed stepwise shifted in the second formation direction and following the first cutting direction.

As a result, the plurality of openings disposed along the first formation direction can be formed virtually along the first cutting direction. Therefore, cutting the light-transmissive substrate as described above still allows the openings to be disposed in desired positions corresponding to the pixels of the display unit.

As described above, since the openings are disposed in desired positions corresponding to the pixels of the display unit, and the pitch along the first cutting direction (row direction) between the openings approaches the ideal opening pitch, a black matrix in the display unit visually recognized through all the openings has substantially the same proportion. That is, the difference due to the black matrix in brightness obtained through the openings can be smaller, whereby a moiré pattern can be suppressed in a stereoscopic image.

Further, since a moiré pattern can be suppressed without unnecessarily reducing the area of the openings, the brightness of a stereoscopic image can be maintained at a sufficient level.

Using the parallax barrier manufactured by using the manufacturing method of the first aspect of the invention therefore allows a stereoscopic image to be displayed in a satisfactory manner.

In the method for manufacturing a parallax barrier according to the first aspect of the invention, the openings are preferably formed stepwise shifted in the second formation direction in such a way that the edge of each of the openings along the first formation direction follows the first cutting direction, and the openings are also preferably formed stepwise shifted in the first formation direction in such a way that the edge of each of the openings along the second formation direction follows the second cutting direction.

In the first aspect of the invention, in the pattern formation step, the openings are formed stepwise in such a way that the edges of each of the openings follow the first cutting direction and the second cutting direction as described above.

In this configuration, cutting the light-transmissive substrate as described above still allows the openings to be formed in such a way that the edges of each of the openings virtually follow the first cutting direction (the row direction of the pixels of the display unit) and the second cutting direction (the column direction of the pixels of the display unit). As a result, when the parallax barrier is combined with the display unit, the openings will not be inclined to the pixels. Therefore, for example, even when the cutting angle is relatively large, a right-eye image and a left-eye image displayed by the pixels of the display unit can be separated in a satisfactory manner, that is, a stereoscopic image can be displayed in a satisfactory manner.

According to a second aspect of the invention, there is provided a method for manufacturing a photomask used to manufacture a parallax barrier that separates a right-eye image and a left-eye image displayed on a display unit having a plurality of pixels arranged in a matrix, the photomask including light blocking portions that block light and openings that transmit light, the photomask used in a photolithography process to form a pattern including an arrangement of the light blocking portions and the openings on the parallax barrier. The method includes a light-blocking layer formation step of forming a light-blocking layer that blocks light on a light-transmissive substrate, a pattern formation step of forming the openings, which are formed of a plurality of rectangular ones, by removing part of the light-blocking layer in such a way that the light blocking portions and the openings are alternately arranged along a first formation direction and a second formation direction perpendicular thereto, and a cutting step of cutting the light-transmissive substrate along a first cutting direction inclined to the first formation direction by a predetermined angle and a second cutting direction inclined to the second formation direction by the angle. In the pattern formation step, the plurality of light blocking portions disposed along the first formation direction are not only formed at an even pitch smaller than an ideal opening pitch for the parallax barrier in a row direction of the display unit, the ideal opening pitch defined based on a pixel pitch in the row direction, but also formed in such a way that the light blocking portions are disposed stepwise shifted in the second formation direction and follow the first cutting direction.

The method for manufacturing a photomask according to the second aspect of the invention is a manufacturing method that is substantially the same as the method for manufacturing a parallax barrier described above except that the light blocking portions and the openings are formed in a photomask with the positions where the light blocking portions and the openings are formed in the parallax barrier reversed.

By manufacturing the parallax barrier by using the photomask in a photolithography process, the same parallax barrier as that manufactured by the method for manufacturing a parallax barrier described above can be manufactured. The same advantageous effects as those provided in the method for manufacturing a parallax barrier described above can therefore be provided.

### BRIEF DESCRIPTION OF THE DRAWINGS

The invention will be described with reference to the accompanying drawings, wherein like numbers reference like elements.

FIG. 1 is a perspective view showing a game machine in a first embodiment.

FIG. 2 is a cross-sectional view diagrammatically showing the configuration of an image display apparatus in the first embodiment.

FIG. 3 is a plan view diagrammatically showing the arrangement of pixels of a liquid crystal panel in the first embodiment.

FIG. 4 is a plan view diagrammatically showing the arrangement of openings in a parallax barrier in the first embodiment.

FIG. 5 is a flowchart describing a method for manufacturing the parallax barrier in the first embodiment.

FIG. 6 describes the method for manufacturing the parallax barrier in the first embodiment.

FIG. 7 describes a method for manufacturing a parallax barrier in a second embodiment.

FIGS. 8A to 8D describe a method for manufacturing a parallax barrier in a third embodiment.

### DESCRIPTION OF EXEMPLARY EMBODIMENTS

### First Embodiment

A first embodiment of the invention will be described below with reference to the drawings.

### Schematic Configuration of Game Machine

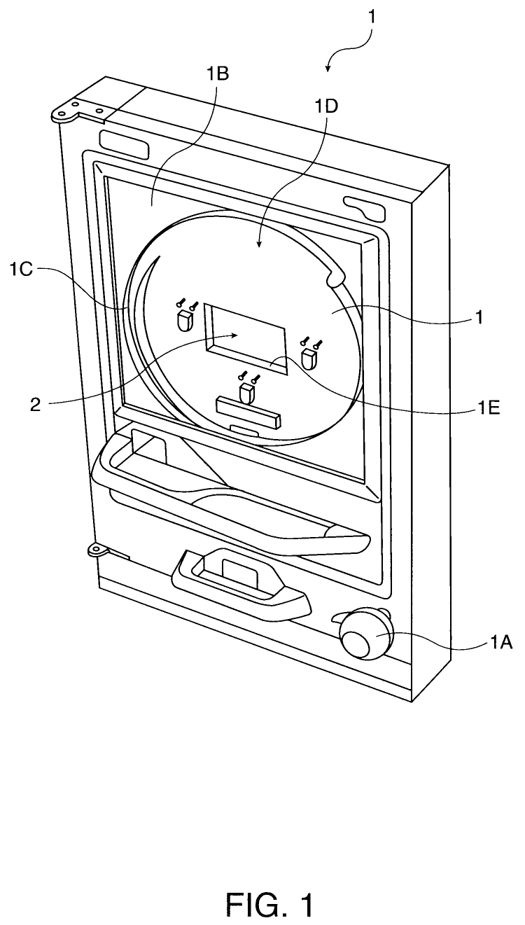

FIG. 1 is a perspective view showing a game machine 1 in the first embodiment.

The game machine 1 is configured as a pachinko machine, as shown in FIG. 1. A pachinko machine is configured to discharge a predetermined number of play balls when a play ball shot from a shooting device (not shown) in response to operation of a handle 1A travels downward on a board of a play board 1B and comes in a predetermined prize hole.

A play area 1D surrounded by a substantially circular sidewall 1C is formed on the front surface of the play board 1B. An image display apparatus 2 is disposed in a substantially central portion of the play area 1D and viewed through a substantially transversely elongated rectangular opening 1E.

### Configurations of Image Display Apparatus

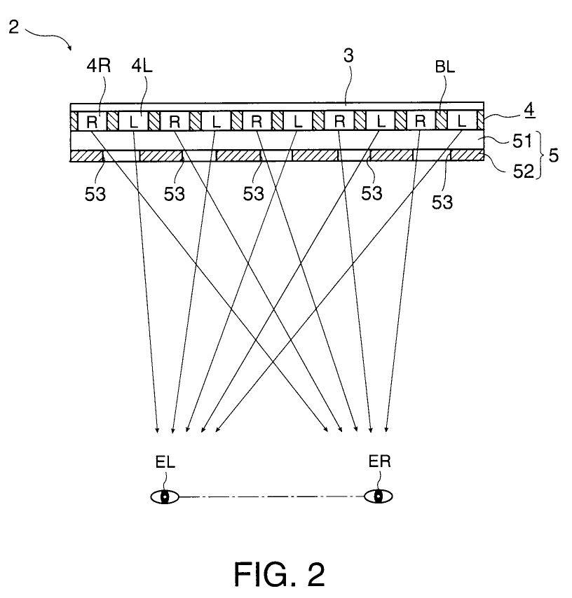

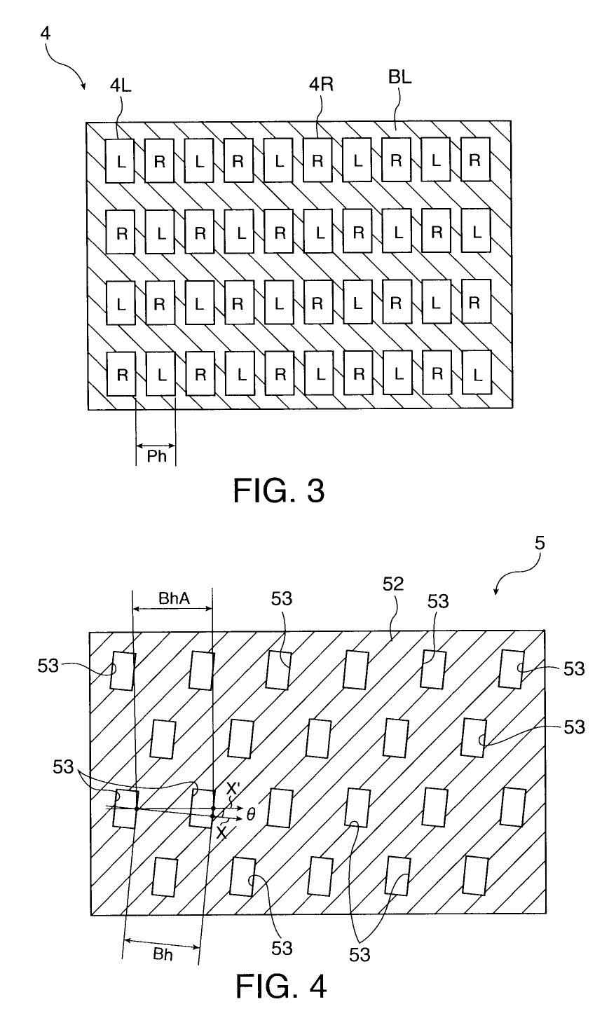

FIG. 2 is a cross-sectional view diagrammatically showing the configuration of the image display apparatus 2. Specifically, FIG. 2 is a cross-sectional view viewed in a column direction (vertical direction: up-down direction in FIGS. 3 and 4) of a liquid crystal panel 4 and a parallax barrier 5.

The image display apparatus 2 receives a command input according, for example, to the result of a lottery held when a play ball comes in a prize hole and displays an image according to the command. Specifically, the image display apparatus 2 produces a stereoscopic image including an image viewed by the right eye of a viewer (right-eye image) and an image viewed by the left eye of the viewer (left-eye image) and displays the stereoscopic image, which is stereoscopically viewable with the aid of parallax when the right-eye and left-eye images are incident on the right and left eyes, respectively. In the present embodiment, the image display apparatus 2 is configured as a binocular stereoscopic display apparatus having two viewpoints.

The image display apparatus 2 includes a backlight 3 as alight source, a liquid crystal panel 4 as a display unit, and a parallax barrier 5, as shown in FIG. 2.

The backlight 3 includes a cold-cathode tube bent into a substantially W-like shape and a reflector disposed behind the cold-cathode tube. In the backlight 3, discharge light produced by applying a voltage to the cold-cathode tube is reflected off the reflector and outputted toward the liquid crystal panel 4. The backlight 3 is not limited to the configuration described above but may have a configuration in which an L-shaped or U-shaped edge-type cold-cathode tube is combined with a light guide plate or a configuration in which the cold-cathode tube and the reflector are replaced with a plurality of LEDs (Light Emitting Diodes) or any other suitable solid-state light sources.

FIG. 3 is a plan view diagrammatically showing the arrangement of pixels 4R and 4L of the liquid crystal panel 4.

In FIGS. 2 and 3, each of the pixels 4R is labeled with a character “R” and each of the pixels 4L is labeled with a character “L” for ease of description. The same applies to the following drawings.

Further in FIGS. 2 and 3, the liquid crystal panel 4 has a configuration in which the pixels 4R and 4L are arranged in four rows by ten columns to simplify the description.

The liquid crystal panel 4 is a fixed-pixel image forming device. The liquid crystal panel 4 includes a plurality of right-eye pixels 4R for displaying a right-eye image and a plurality of left-eye pixels 4L for displaying a left-eye image, and the pixels 4R and 4L are separated by a black matrix BL, as shown in FIG. 2 or 3.

The right-eye pixels 4R and the left-eye pixels 4L are alternately arranged in all row directions (horizontal direction: right-left direction in FIG. 3) and all column directions (vertical direction: up-down direction in FIG. 3), as shown in FIG. 3.

The pixels 4R and 4L, although not shown specifically, form subpixels with R (red), G (green), and B (blue) color filters disposed on the light flux exiting side. Each of the pixels 4R and 4L includes a TFT (Thin Filmed Transistor) as a switching device for applying a voltage to liquid crystal molecules sealed and encapsulated between a pair of transparent substrates. The voltage applied, as an image signal, to each of the pixels 4R and 4L is changed when the TFT is switched, and hence the orientation of the liquid crystal molecules is changed. The incident light flux is thus modulated in accordance with the image signal.

FIG. 4 is a plan view diagrammatically showing the arrangement of openings 53 in the parallax barrier 5.

The parallax barrier 5 is disposed on the light flux exiting side of the liquid crystal panel 4 (viewer's side) (FIG. 2) and functions to separate a right-eye image and a left-eye image that form a stereoscopic image to be displayed so that the images are separately incident on the eyes of the viewer.

The parallax barrier 5 includes a light-transmissive substrate 51, which transmits light having passed through the liquid crystal panel 4, and a light blocker 52, as shown in FIG. 2.

The light blocker 52 is made of a light-blocking material and formed on the light-transmissive substrate 51. As shown in FIG. 4, in the light blocker 52, rectangular openings 53 are disposed in every other column in the row direction (horizontal direction: right-left direction in FIG. 4) at a predetermined even pitch in correspondence with the arrangement of the pixels 4R and 4L of the liquid crystal panel 4. The openings 53 are also disposed in every other row in the column direction (vertical direction: up-down direction in FIG. 4) at a predetermined even pitch. That is, the openings 53 are disposed in a staggered pattern.

All the openings 53 have the same shape.

How the viewer recognizes a stereoscopic image through the parallax barrier 5 described above follows.

That is, the light blocker 52 prevents the light that exits from the left-eye pixels 4L from entering the right eye ER of the viewer but allows the light to enter only the left eye EL of the viewer through the openings 53, as shown in FIG. 2.

Similarly, the light blocker 52 prevents the light that exits from the right-eye pixels 4R from entering the left eye EL of the viewer but allows the light to enter only the right eye ER of the viewer through the openings 53, as shown in FIG. 2.

The viewer then recognizes a stereoscopic image with the aid of the parallax between the right-eye image and the left-eye image.

### Method for Manufacturing Parallax Barrier

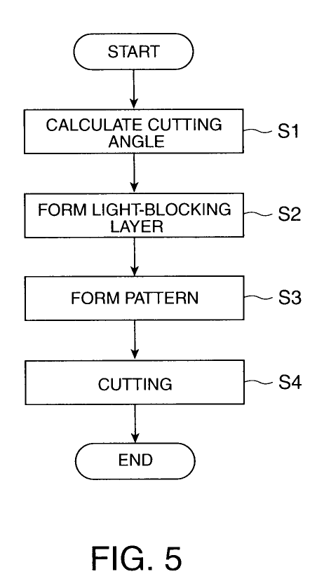

FIG. 5 is a flowchart describing a method for manufacturing the parallax barrier 5.

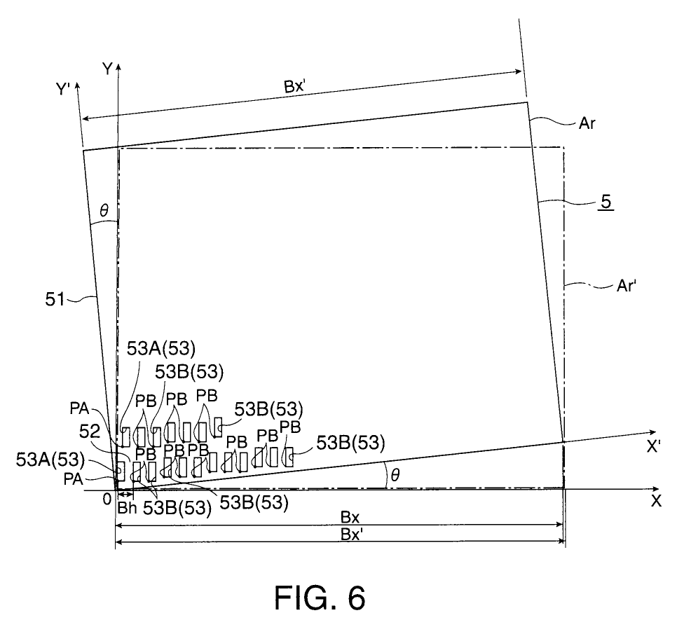

FIG. 6 describes the method for manufacturing the parallax barrier 5. FIG. 6 shows a state in which only part of the openings 53 is formed.

For example, the parallax barrier 5 described above is manufactured as follows.

The method for manufacturing the parallax barrier 5 will be illustrated based on the following liquid crystal panel for ease of description.

Liquid crystal panel 4: 12-inch size XGA panel (the diagonal thereof is approximately 31 cm long)

Pixel pitch Pₕ in row direction (horizontal direction) (FIG. 3): 0.08 mm

Width of screen in row direction (FIG. 3): pixel pitch Pₕ×3 (RGB subpixels)×1024=245.76 mm

In a typical method for manufacturing a parallax barrier, the light blocking portions and the openings are formed in a pattern on the light-transmissive substrate in such a way that the light blocking portions and the openings are alternately disposed along a first formation direction X (FIG. 6) and a second formation direction Y (FIG. 6) perpendicular to the first formation direction. The light-transmissive substrate is then cut along the first formation direction X and the second formation direction Y to achieve the size of the parallax barrier (the rectangular area Ar′ indicated by the dashed line in FIG. 6) that is necessary to separates left-eye and right-eye images displayed by the pixels 4R and 4L of the liquid crystal panel 4.

In contrast, in the present application, the light-transmissive substrate is cut along a first cutting direction X′ inclined to the first formation direction X by a predetermined cutting angle θ (FIG. 6) and a second cutting direction Y′ inclined to the second formation direction Y by the cutting angle θ (FIG. 6) in a cutting step S4, which will be described later.

In the manufacturing method of the present application, the cutting angle θ described above is first calculated (step S1: angle calculation step) as follows.

Although will be specifically described later, the width of the openings 53 and the width of the light blocking portions 52 along the first formation direction X (hereinafter referred to as an opening width and a light blocking width) and a horizontal opening pitch Bₕ (FIGS. 4 and 6) between the openings 53 along the first formation direction X are set at the following values in a pattern formation step S3, which will be described later.

Opening width: 0.06 mm

Light blocking width: 0.099 mm

Horizontal opening pitch Bₕ: 0.159 mm

A theoretically ideal opening pitch Bₕ′ between the openings 53 in the row direction is expressed by the following Equation (1):

$${B}_{h}^{′} = \frac{2 {P}_{h} E}{{P}_{h} + E} \qquad ( 1 )$$

where E represents the interpupillary distance.

For example, the ideal opening pitch Bₕ′ is calculated by Equation (1) to be 0.159803 . . . mm when the interpupillary distance E is 65 mm.

It is noted that current pattern forming methods (laser etching, dry etching, wet etching, photolithography, or other methods) only allow the light blocking portions 52 and the openings 53 to be formed with precision up to approximately 1 μm.

That is, current pattern forming methods achieve a horizontal opening pitch Bₕ of 0.159 mm or 0.160 mm but do not achieve the ideal opening pitch Bₕ′ described above.

In the present embodiment, since the horizontal opening pitch Bₕ is 0.159 mm as described above, which is smaller than the ideal opening pitch Bₕ′, current pattern formation methods suffice to form desired openings.

A required total horizontal width Bₓ′ (FIG. 6) of the parallax barrier 5 that is necessary to separate a left-eye image and a right-eye image displayed by the pixels 4R and 4L of the liquid crystal panel 4 is determined as follows.

That is, the required total horizontal width Bₓ′ is given by n×Bₕ, where the number of pitches between the openings 53 is n.

The number of pitches n is 245.76/Bₕ′≈1538 because the screen width (245.76 mm) in the row direction of the liquid crystal panel 4 needs to be covered.

The required total horizontal width Bₓ′ is therefore 1538×Bₕ′=245.77504 . . . mm.

On the other hand, since the horizontal opening pitch Bₕ achievable even by using a current pattern forming method and having actually been achieved is 0.159 mm as described above, a total horizontal width Bₓ (FIG. 6) in an achievable row direction (first formation direction X) is 1538×Bₕ=245.542 mm, which is smaller than the required total horizontal width Bₓ′.

The parallax barrier 5 can be cut to be the required total horizontal width Bₓ′, even when the horizontal opening pitch Bₕ is used to form the openings 53, by cutting the parallax barrier 5 along the first cutting direction X′ inclined to the first formation direction X by the cutting angle θ, which is given by the following equation (2), and the second cutting direction Y′ inclined to the second formation direction Y by the cutting angle θ, as shown in FIG. 6.

$$θ = arccos ( \frac{{B}_{x}}{{B}_{x}^{′}} ) \approx 0.1003 ( rad ) \qquad ( 2 )$$

The same cutting angle θ can be calculated by using the following equation (3) based on the horizontal opening pitch Bₕ and the ideal opening pitch Bₕ′.

$$θ = arccos ( \frac{{B}_{h}}{{B}_{h}^{′}} ) \approx 0.1003 ( rad ) \qquad ( 3 )$$

After the angle calculation step S1, a light-blocking material that forms the light blocking portions 52 is applied onto the entire surface of the light-transmissive substrate 51 to form a light-blocking layer (step S2: light-blocking layer formation step).

After the light-blocking layer formation step S2, laser etching is used to remove part of the light-blocking layer to form a plurality of substantially rectangular openings 53 in such a way that the light blocking portions 52 and the openings 53 are alternately arranged along the first formation direction X and the second formation direction Y (step S3: pattern formation step).

Specifically, in the pattern formation step S3, a rotation mapping function (X, Y) expressed by the following equation (4) is used to identify the position where each of the openings 53 is formed. All the openings 53 are then formed by forming a plurality of openings 53 (hereinafter referred to as a row pattern) along the row direction (first formation direction X) and repeatedly forming the row pattern along the second formation direction Y.

X=x×cos θ−y×sin θ

Y=x×sin θ+y×cos θ (4)

In Equation (4), X and Y represent the coordinates after the rotation mapping is performed; x and y represent the coordinates before the rotation mapping is performed; and θ represents the cutting angle calculated in the angle calculation step S1.

For example, Equation (4) is used to identify the position where each of the openings 53 is formed, as described below.

That is, the X coordinate of a lower left corner position PA (FIG. 6) of an opening 53A (FIG. 6) positioned at the leftmost end of the corresponding row pattern is calculated by substituting zero into x and the theoretical height position of the row pattern having not undergone the rotation mapping into y in the Equation (4).

Further, the Y coordinates of the lower left corner positions PA (FIG. 6) of each of the openings 53 are calculated by substituting the x and y coordinates of the theoretical lower left corner position of the opening 53 having not undergone the rotation mapping into x and y in the Equation (4).

After the coordinates (X, Y) of the lower left corner position PA of the opening 53A positioned at the leftmost end of the row pattern are identified as described above, the opening 53A is formed by using the lower left corner position PA as a formation initiation position and using the opening width of 0.06 mm and the height of the opening 53A of 0.18 mm along the second formation direction Y (hereinafter referred to as an opening height).

After the opening 53A is formed, another opening 53B (FIG. 6) adjacent thereto is formed along the first formation direction X.

Specifically, the X coordinate of the lower left corner position PB of another opening 53B is obtained by adding the horizontal opening pitch Bₕ to the X coordinate of the lower left corner position PA of the opening 53A, and the Y coordinate of the lower left corner position PB has been calculated as described above.

The opening 53B is formed by using the lower left corner position PB as the formation initiation position and using the opening width of 0.06 mm and the opening height of 0.18 mm, as described above.

The row pattern is formed by successively forming openings 53 along the first formation direction X, as described above. Further, all the openings 53 are formed by successively forming the row pattern along the second formation direction Y.

In the formation method described above, the openings 53 disposed along the first formation direction X are disposed stepwise and follow the first cutting direction X′, as shown in FIG. 6. Although not shown specifically, the openings 53 disposed along the second formation direction Y are also disposed stepwise and follow the second cutting direction Y′.

After the pattern formation step S3, the light-transmissive substrate 51 is cut along the first cutting direction X′ and the second cutting direction Y′ (step S4: cutting step).

Cutting the light-transmissive substrate 51 in the cutting step S4 allows the manufactured parallax barrier 5 to have the size necessary to separate a left-eye image and a right-eye image displayed by the pixels 4R and 4L of the liquid crystal panel 4 (the size equivalent to the rectangular area Ar′).

According to the first embodiment described above, the following advantageous effects are provided.

In the present embodiment, when part of the light-blocking layer is removed to form a plurality of rectangular openings 53 in the pattern formation step S3, a plurality of openings 53 disposed along the first formation direction X are formed at the horizontal opening pitch Bₕ achievable by a current pattern forming method and smaller than the ideal opening pitch Bₕ′. The parallax barrier 5 is then manufactured in the cutting step S4 by cutting the light-transmissive substrate 51 into the rectangular area Ar along the first cutting direction X′ inclined to the first formation direction X by the cutting angle θ and the second cutting direction Y′ inclined to the second formation direction Y by the cutting angle θ.

When the thus manufactured parallax barrier 5 is combined with the liquid crystal panel 4 in such a way that the row direction of the pixels 4R and 4L of the liquid crystal panel 4 is aligned with the first cutting direction X′, the pitch BₕA (FIG. 4) along the first cutting direction X′ (row direction) between the openings 53 can be virtually closer to the ideal opening pitch Bₕ′ even when the horizontal opening pitch Bₕ, which is smaller than the ideal opening pitch Bₕ′, is provided in the pattern formation step S3.

In the present embodiment, in particular, since the cutting angle θ is given by arccos(Bₕ/Bₕ′) as indicated by Equation (3), the pitch BₕA can be substantially equal to the ideal opening pitch Bₕ′.

Further, in the pattern formation step S3, the plurality of openings 53 disposed along the first formation direction X are formed stepwise shifted in the second formation direction Y and following the first cutting direction X′.

As a result, the plurality of openings 53 disposed along the first formation direction X can be formed virtually along the first cutting direction X′. Therefore, cutting the light-transmissive substrate 51 as described above still allows the openings 53 to be disposed in desired positions corresponding to the pixels 4R and 4L of the liquid crystal panel 4.

As described above, since the openings 53 are disposed in desired positions corresponding to the pixels 4R and 4L of the liquid crystal panel 4, and the pitch BₕA along the first cutting direction X′ (row direction) between the openings 53 approaches the ideal opening pitch Bₕ′, the black matrix BL in the liquid crystal panel 4 visually recognized through all the openings 53 has substantially the same proportion. That is, the difference due to the black matrix BL in brightness obtained through the openings 53 can be smaller, whereby a moiré pattern can be suppressed in a stereoscopic image.

Further, since a moiré pattern can be suppressed without unnecessarily reducing the area of the openings 53, the brightness of a stereoscopic image can be maintained at a sufficient level.

### Second Embodiment

A second embodiment of the invention will next be described with reference to the drawings.

In the following description, the same structures and members as those in the first embodiment have the same reference characters, and detailed descriptions thereof will be omitted or simplified.

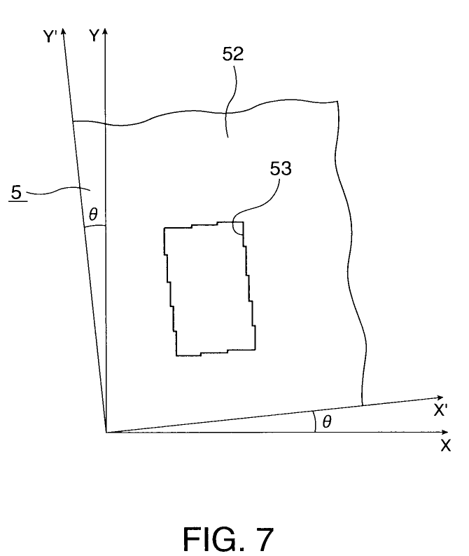

FIG. 7 describes a method for manufacturing a parallax barrier 5 in the second embodiment.

In the first embodiment, when the openings 53 are formed in the pattern formation step S3, the edges of each of the openings 53 are parallel to the first formation direction X and the second formation direction Y, and each of the openings 53 has a rectangular shape.

In contrast, the second embodiment only differs from the first embodiment in that when the openings 53 are formed in the pattern formation step S3, the openings 53 are formed stepwise in such a way that the edges of each of the openings 53 follow the first cutting direction X′ and the second cutting direction Y′ as shown in FIG. 7.

According to the second embodiment described above, not only are the same advantageous effects as those in the first embodiment provided but also the following advantageous effects are provided.

In the present embodiment, in the pattern formation step S3, the openings 53 are formed stepwise in such away that the edges of each of the openings 53 follow the first cutting direction X′ and the second cutting direction Y′ as described above.

In this configuration, cutting the light-transmissive substrate 51 along the first cutting direction X′ and the second cutting direction Y′ in the cutting step S4 still allows the openings 53 to be formed in such a way that the edges of each of the openings 53 virtually follow the first cutting direction X′ (the row direction of the pixels 4R and 4L of the liquid crystal panel 4) and the second cutting direction Y′ (the column direction of the pixels 4R and 4L of the liquid crystal panel 4). As a result, when the parallax barrier 5 is combined with the liquid crystal panel 4, the openings 53 will not inclined to the pixels 4R or 4L. Therefore, for example, even when the cutting angle θ is relatively large, a right-eye image and a left-eye image displayed by the pixels 4R and 4L of the liquid crystal panel 4 can be separated in a satisfactory manner, that is, a stereoscopic image can be displayed in a satisfactory manner.

### Third Embodiment

A third embodiment of the invention will next be described with reference to the drawings.

In the following description, the same structures and members as those in the first embodiment have the same reference characters, and detailed descriptions thereof will be omitted or simplified.

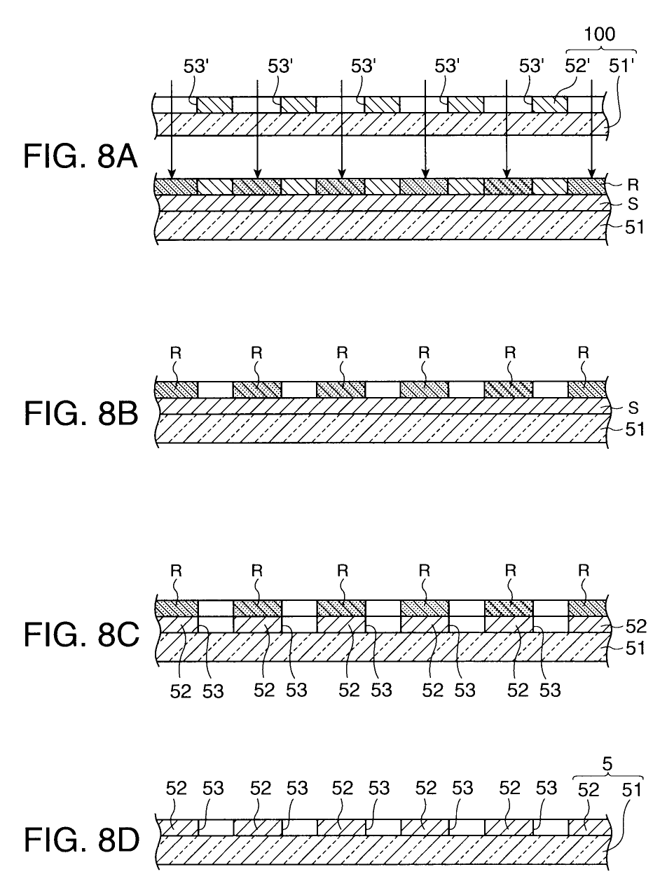

FIGS. 8A to 8D describe a method for manufacturing a parallax barrier 5 in the third embodiment.

In the first embodiment described above, to manufacture the parallax barrier 5, the light-blocking layer is formed on the light-transmissive substrate 51 in the light-blocking layer formation step S2, and laser etching is then used to directly remove part of the light-blocking layer to form a plurality of openings 53 in the pattern formation step S3.

In contrast, the third embodiment only differs from the first embodiment in that, to manufacture the parallax barrier 5, a photomask 100 having light blocking portions 52′ and openings 53′ on a light-transmissive substrate 51 are used in a photolithography process to form light blocking portions 52 and openings 53 in the parallax barrier 5 as shown in FIGS. 8A and 8D.

That is, the photomask 100 needs to be configured in such a way that the shape of the light blocking portions 52′ is the same as the shape of the openings 53 in the parallax barrier 5 and the shape of the openings 53′ is the same as the shape of the light blocking portions 52 in the parallax barrier 5.

To this end, a method for manufacturing the photomask 100 can be a method that is substantially the same as the method for manufacturing the parallax barrier 5 described in the first embodiment except that a plurality of rectangular light blocking portions 52 may be formed in the pattern formation step S3 with the positions where the light blocking portions 52 and the openings 53 are formed reversed. That is, in FIG. 4 or 6, the openings 53′ are formed in the positions where the light blocking portions 52 are formed, and the light blocking portions 52′ are formed in the positions where the openings 53 are formed.

The parallax barrier 5 is then manufactured by using the thus manufactured photomask 100 as described below.

First, a light-blocking layer S is formed on and a resist R is applied onto the entire surface of the light-transmissive substrate 51, as shown in FIG. 8A. The thus formed substrate is exposed to light through the photomask 100 so that the resist R corresponding to the openings 53′ in the photomask 100 is exposed to light.

The portions of the resist R other than the areas having been exposed to light are then removed in development and cleaning processes, as shown in FIG. 8B.

The areas of the light-blocking layer S that are not covered with the resist R having been exposed to light are then removed by etching, as shown in FIG. 8C.

The same parallax barrier 5 as that provided in the first embodiment is manufactured by removing the resist R having been exposed to light, as shown in FIG. 8D.

The parallax barrier 5 manufactured by using the photomask 100 in a photolithography process in the third embodiment described above still allows the same advantageous effects as those in the first embodiment to be provided.

The invention is not limited to the embodiments described above but encompasses changes, modifications, and other variations to the extent that they achieve the purpose of the invention.

In each of the embodiments described above, the horizontal opening pitch Bₕ (the pitch along the first formation direction X between the light blocking portions 52′ in the third embodiment) is not limited to the value described in the embodiment but may be any other value that is smaller than the ideal opening pitch Bₕ′.

In each of the embodiments described above, when the position where each of the openings 53 (each of the light blocking portions 52′ in the third embodiment) is formed is identified in the pattern formation step S3, the rotation mapping function expressed by the Equation (4) is used. Instead, any other method may be used to identify the position where each of the openings 53 is formed.

In each of the embodiments described above, the parallax barrier 5 is disposed on the light exiting side of the liquid crystal panel 4. The parallax barrier 5 may instead be disposed between the backlight 3 and the liquid crystal panel 4. In this case, since the ideal opening pitch Bₕ′ differs from the value described in each of the embodiments described above, the pattern formation step S3 may be carried out in such a way that the horizontal opening pitch Bₕ is smaller than an ideal opening pitch Bₕ′ different from the value described in the embodiment.

In the third embodiment described above, the light blocking portions 52′ may be formed stepwise in such a way that the edges of each of the blocking portions 52′ follow the first cutting direction X′ and the second cutting direction Y′, as in the second embodiment.

Each of the above embodiments has been described with reference to the case where the image display apparatus 2 includes the liquid crystal panel 4, but the invention is not limited thereto. That is, the backlight 3 and the liquid crystal panel 4 may be replaced with a panel including self-luminous devices based on organic EL (Electro-Luminescence), plasma, or any other technology, or even with a CRT (Cathode Ray Tube).

Each of the above embodiments has been described with reference to the case where the image display apparatus 2 is used in the game machine 1 configured as a pachinko machine, but the image display apparatus 2 is not necessarily used this way. That is, the image display apparatus 2 can be used in a pachinko-slot machine or any other similar game machine. Further, the image display apparatus 2 can be used as a standalone apparatus or used in an automotive console panel, a video game, or any other similar apparatus.

The invention can be used in a method for manufacturing a parallax barrier that is used in combination with a display unit having a plurality of pixels and separates a right-eye image and a left-eye image displayed on the display unit.

What is claimed is:

1. A method for manufacturing a parallax barrier including light blocking portions that block light and openings that transmit light, the light blocking portions and the openings separating a right-eye image and a left-eye image displayed on a display unit having a plurality of pixels arranged in a matrix, the method comprising:
a light-blocking layer formation step of forming a light-blocking layer that blocks light on a light-transmissive substrate;
a pattern formation step of forming the openings, which are formed of a plurality of rectangular ones, by removing part of the light-blocking layer in such a way that the light blocking portions and the openings are alternately arranged along a first formation direction and a second formation direction perpendicular thereto; and
a cutting step of cutting the light-transmissive substrate along a first cutting direction inclined to the first formation direction by a predetermined angle and a second cutting direction inclined to the second formation direction by the angle,
in the pattern formation step, the plurality of openings disposed along the first formation direction are not only formed at an even pitch smaller than an ideal opening pitch for the parallax barrier in a row direction of the display unit, the ideal opening pitch defined based on a pixel pitch in the row direction, but also formed in such a way that the openings are disposed stepwise shifted in the second formation direction and follow the first cutting direction.

2. The method for manufacturing a parallax barrier according to claim 1,
wherein in the pattern formation step,
the openings are formed stepwise shifted in the second formation direction in such a way that the edge of each of the openings along the first formation direction follows the first cutting direction, and
the openings are also formed stepwise shifted in the first formation direction in such a way that the edge of each of the openings along the second formation direction follows the second cutting direction.

3. A method for manufacturing a photomask used to manufacture a parallax barrier that separates a right-eye image and a left-eye image displayed on a display unit having a plurality of pixels arranged in a matrix, the photomask including light blocking portions that block light and openings that transmit light, the photomask used in a photolithography process to form a pattern including an arrangement of the light blocking portions and the openings on the parallax barrier, the method comprising:
a light-blocking layer formation step of forming a light-blocking layer that blocks light on a light-transmissive substrate;
a pattern formation step of forming the openings, which are formed of a plurality of rectangular ones, by removing part of the light-blocking layer in such a way that the light blocking portions and the openings are alternately arranged along a first formation direction and a second formation direction perpendicular thereto; and
a cutting step of cutting the light-transmissive substrate along a first cutting direction inclined to the first formation direction by a predetermined angle and a second cutting direction inclined to the second formation direction by the angle,
in the pattern formation step, the plurality of light blocking portions disposed along the first formation direction are not only formed at an even pitch smaller than an ideal opening pitch for the parallax barrier in a row direction of the display unit, the ideal opening pitch defined based on a pixel pitch in the row direction, but also formed in such a way that the light blocking portions are disposed stepwise shifted in the second formation direction and follow the first cutting direction.
